(19) United States
(12) Patent Application Publication
(10) Pub. No.: US 2009/0120486 A1
(43) Pub. Date: May 14, 2009

(54) Bifacial Solar Cell Array

(76) Inventor: Benyamin Buller, Cupertino, CA (US)

Correspondence Address: JONES DAY, 222 EAST 41ST ST, NEW YORK, NY, 10017, US

(21) Appl. No.: 11/934,327

(22) Filed: Nov. 2, 2007

Related U.S. Application Data
(60) Provisional application No. 60/859,033, filed on Nov. 15, 2006.
(60) Provisional application No. 60/859,188, filed on Nov. 15, 2006.
(60) Provisional application No. 60/859,212, filed on Nov. 15, 2006.
(60) Provisional application No. 60/859,213, filed on Nov. 15, 2006.
(60) Provisional application No. 60/859,215, filed on Nov. 15, 2006.
(60) Provisional application No. 60/861,162, filed on Nov. 27, 2006.
(60) Provisional application No. 60/901,517, filed on Feb. 14, 2007.

(51) Int. Cl. H01L 31/052

(52) U.S. Cl. 136/246

(57) ABSTRACT

First and second solar panels are mounted in an operative position. Each panel includes an upward-facing photovoltaic surface and a downward-facing photovoltaic surface that are configured to photovoltaically generate electricity from light. The downward-facing photovoltaic surface is spaced above a reflective surface. The first and second panels are spaced apart in a first direction by a spacing distance that is about 25% to about 100% of the width of the first panel in the first direction. Some downwardly-directed light rays can strike the upward-facing photovoltaic surfaces of the panels. Other downwardly-directed light rays can pass between the first and second panels and be reflected upward by the reflective surface to strike the downward-facing photovoltaic surfaces of the panels.

### CROSS-REFERENCE TO RELATED APPLICATION

This claims the benefit of U.S. Provisional Application Nos. 60/859,033, 60/859,188, 60/859,212, 60/859,213, 60/859,215 and 60/859,162, all filed Nov. 15, 2006, and U.S. Provisional Application No. 60/901,517, filed Feb. 14, 2007, all seven applications hereby incorporated by reference.

### TECHNICAL FIELD

This application relates to solar panels.

### BACKGROUND

A solar panel includes an array of photovoltaic modules that output electricity when exposed to sunlight.

### BRIEF DESCRIPTION OF THE DRAWINGS

FIG. 1 is a perspective view of a first array of solar panels, each panel including one planar photovoltaic module.

FIG. 2 is an exploded view of the one of the modules shown in FIG. 1.

FIG. 3A is a sectional view taken at line 3A-3A of FIG. 1, showing two of the panels resting on the ground and exposed to sunlight.

FIG. 3B is an expanded view of section 3B of FIG. 3A.

FIG. 4 is a perspective view of a second array of solar panels, each panel including multiple elongated photovoltaic modules.

FIG. 5 is a side sectional view, taken at line 5-5, of one of the panels of FIG. 4, showing the elongated modules in a one-dimensional array.

FIG. 6 is an expanded sectional view of one of the elongated modules of FIG. 5.

FIG. 7 is a sectional view similar to FIG. 5, showing an alternative embodiment with the elongated modules in a two-dimensional array.

FIG. 8 is a sectional view similar to FIG. 3A, showing an alternative embodiment in which the panels rest on a reflecting surface located above the ground.

### DESCRIPTION

### First Embodiment

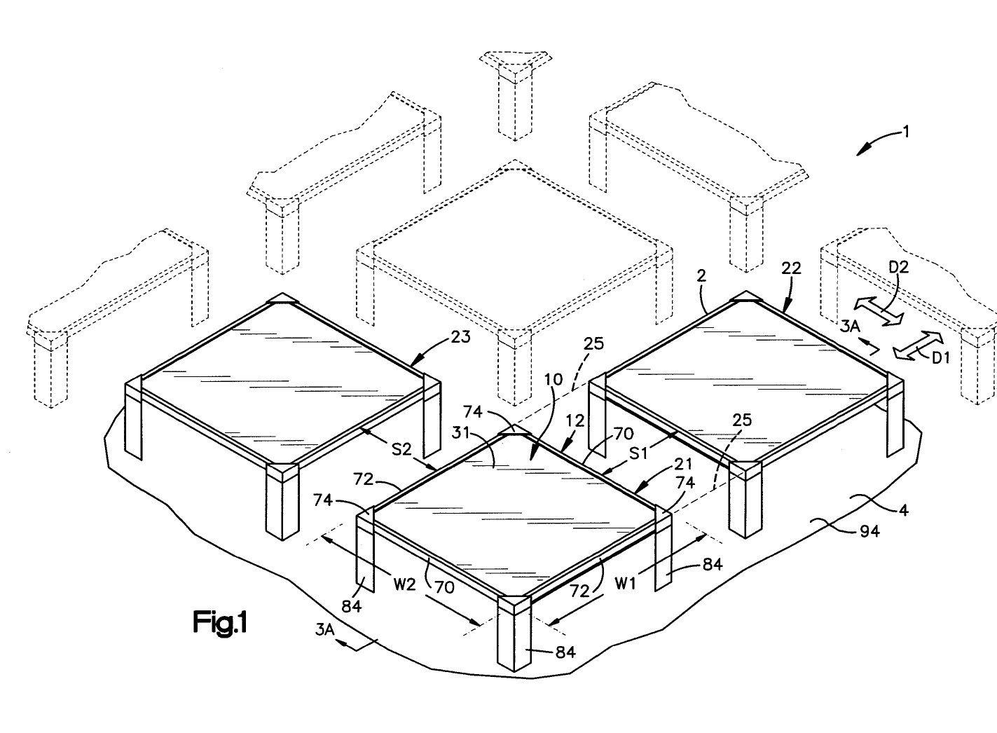

The apparatus 1 shown in FIG. 1 has parts that are examples of the elements recited in the claims. These examples enable a person of ordinary skill in the art to make and use the invention and include best mode without imposing limitations not recited in the claims. Features from different embodiments described below can be combined together in one embodiment in practicing the invention without departing from the scope of the claims.

The apparatus 1 in FIG. 1 is an array of solar panels 2. The panels 2 are mounted on a support surface 4 in an operative position for generating electricity from sunlight. Each panel 2 includes a flat photovoltaic module 10 secured in a frame 12. The support surface 4 is preferably flat, horizontal, and configured to be walked on—typically the surface of the ground or a roof.

The panels 2 include first, second and third panels 21, 22, 23. They can be identical and are described with reference to the first panel 21. The first panel 21 has a first width W₁ in a first direction D₁. It also has a second width W₂ in a second direction D₂ perpendicular to the first direction D₁.

The first and second panels 21, 22 are spaced apart in the first direction D₁ by a first spacing distance S₁ that is about 25% to about 100% of the first width W₁. Similarly, the second and third panels 22, 23 are spaced apart in the second direction D₂ by a second spacing distance S₂ that is about 25% to about 100% of the second width W₂.

A horizontal area defined by and between the first and second panels 21, 22 is bounded by imaginary lines 25 in FIG. 1. This area is about 25% to about 100% of the horizontal area covered by the first panel 21, which in this example equals W₁×W₂. Similarly, the horizontal area defined by and between the first and third panels 21, 23 is about 25% to about 100% of the horizontal area covered by the first panel 21. In an array with multiple rows of multiple panels, the total horizontal area that is not covered by the panels 2 (FIG. 1) is preferably about 50% to about 300% of the total horizontal area that is covered by the panels 2.

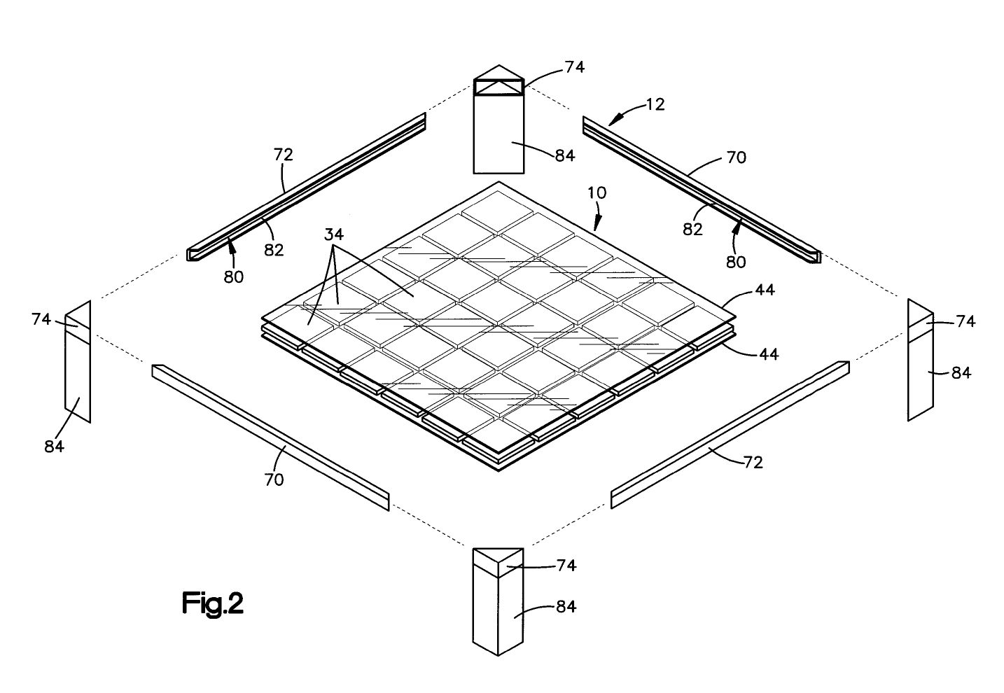

As shown in FIG. 2, the photovoltaic module 10 can include separate photovoltaic units 34 sandwiched between upper and lower transparent glass plates 44 that support and protect the units 34.

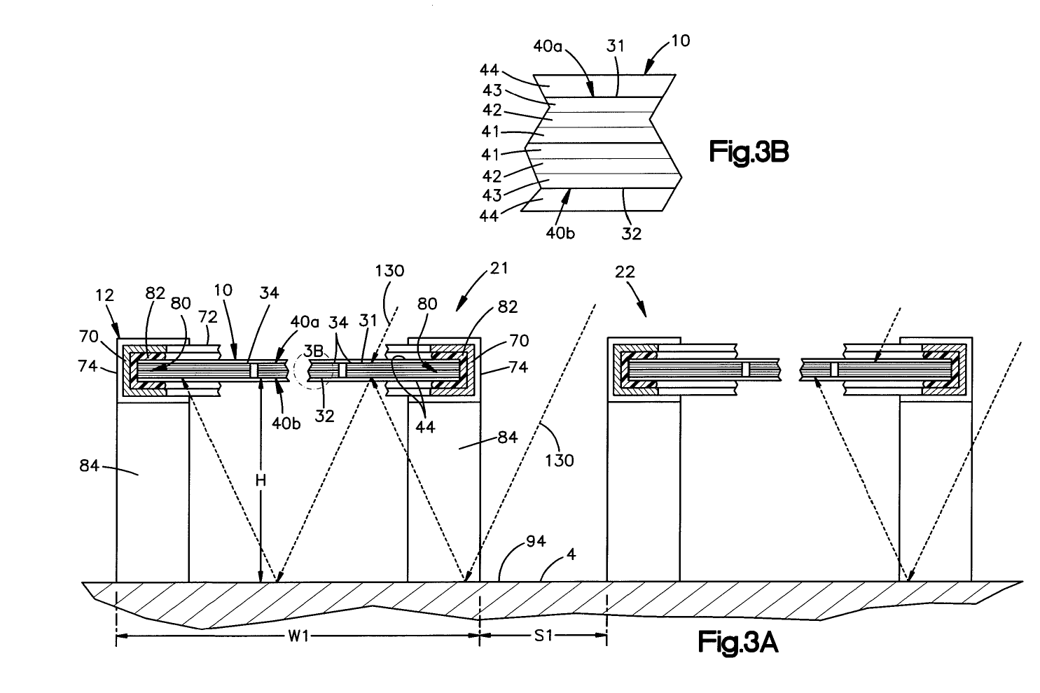

As shown in FIG. 3A, the photovoltaic module 10 is bifacial in that it can photovoltaically generate electricity from light striking its top surface 31 and from light striking its bottom surface 32. This can be achieved, for example, by each photovoltaic unit 34 having upper and lower photocells 40a, 40b arranged back-to-back, so that the unit 34 is itself bifacial.

As shown in FIG. 3B, each photocell 40a, 40b typically has three layers—a conductive inner layer 41, a semiconductor photovoltaic middle layer 42, and a transparent conductive outer layer 43. The two inner layers 41 can be combined or sandwiched about a support plate. Accordingly, in this example, the module's upward-facing and downward-facing photovoltaic surfaces 31, 32 are each provided by multiple separate photocells 40a, 40b.

The upper and lower photocells 40a, 40b of each bifacial unit 34 can be electrically interconnected. Similarly, the multiple bifacial units 34 (FIG. 2) of each module 10 can be electrically interconnected, and the multiple modules 10 of the array 1 (FIG. 1) can be electrically interconnected to output electricity through a common pair of outlet terminals when the modules 10 are exposed to light. The interconnections can be in series, parallel or a combination of both.

As shown in FIGS. 1-2, the frame 12 includes two opposite side rails 70 and two opposite end rails 72 connected together by corner brackets 74. In this example, the side rails 70 and end rails 72 can have the same cross-section, can be cut from the same extruded stock material, and are preferably the same length. Each rail 70, 72 has a groove 80 that receives a respective peripheral edge of the photovoltaic module 10. The module 10 can be secured and/or cushioned in the channel by a gasket 82 with a U-shaped cross-section, or by potting material that is poured in the channel and hardened in place, or by some other packing material. The frame 12, like the photovoltaic module 10, is preferably square, with its first and second widths W₁ and W₂ differing by less than about 5% or 15%. The widths W₁ and W₂ of the panel 21 respectively equal the widths of the frame 12.

A support structure spaces the module 10 above the support surface 4. In this example, the support structure includes four legs 84, one adjoined to each corner bracket of the frame 12 to support the panel 21 on the support surface 4. The legs 84 can be secured to the ground 4. Alternatively, the legs 84 can simply rest on the ground 4 without being secured to it, to enable the panels 21 to be more easily moved and/or removed for maintenance.

As shown in FIG. 3A, portions of the support surface 4 serve as a reflecting surface 94 to reflect light upward toward the downward-facing photovoltaic surface 32. The reflecting surface 94 can be a light-diffusing surface, such as a paint coating or a gravel surface or the surface of the ground or a roof. The module 10 can be maintained in a fixed orientation, such as parallel to the reflective surface 94, without solar tracking. The reflecting surface 94 extends both directly under each panel 21, 22, 23 (FIG. 1) and between the panels 21, 22, 23. The legs 84 are preferably sized for the height H of the downward-facing photovoltaic surface 32 from the reflective surface 94 to be about 25% to about 100% of the widths W₁ and W₂ (FIG. 1) of the panel 21 in the first and second directions D₁ and D₂.

Downward-directed light rays 130 can strike the upward-facing photovoltaic surface 31 directly. Light 130 passing between the first and second panels 21, 22, as well as light passing between the first and third panels 21, 23 (FIG. 1), can be reflected by the reflective surface 94 upward toward the downward-facing photovoltaic surface 32, and can even be reflected multiple times between the reflective surface 94 and the downward-facing photovoltaic surface 32.

The spacing between adjacent panels 21-23 (FIG. 1) thus provides room for light 130 to reach the reflecting surface 94. The spacing also provides room for a person to walk between the panels 21-23 when maintaining and/or replacing panels 21-23. Although relationships relating to width, height and spacing are described herein with reference to the first panel 21 and its neighboring panels 22, 23, these relationships can apply to any number of panels arranged in one or more rows.

### Alternative Embodiments

In the figures cited below, parts labeled with primed and multiply-primed reference numerals correspond to parts labeled in other figures with equivalent unprimed numerals.

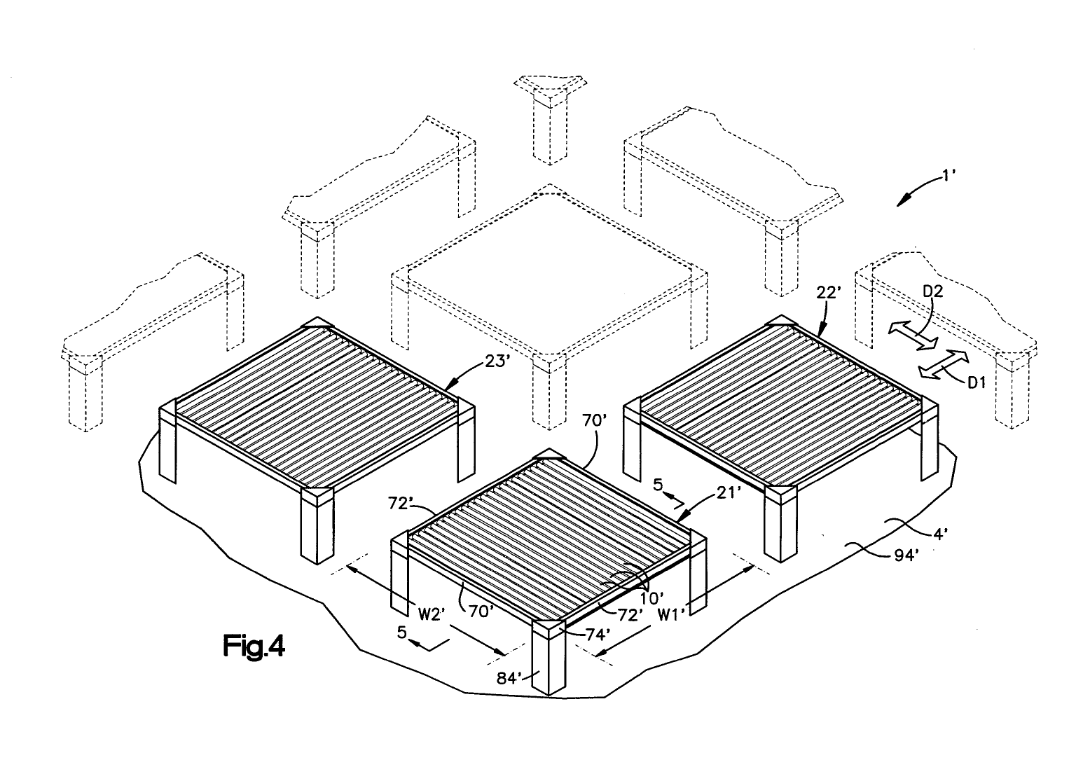

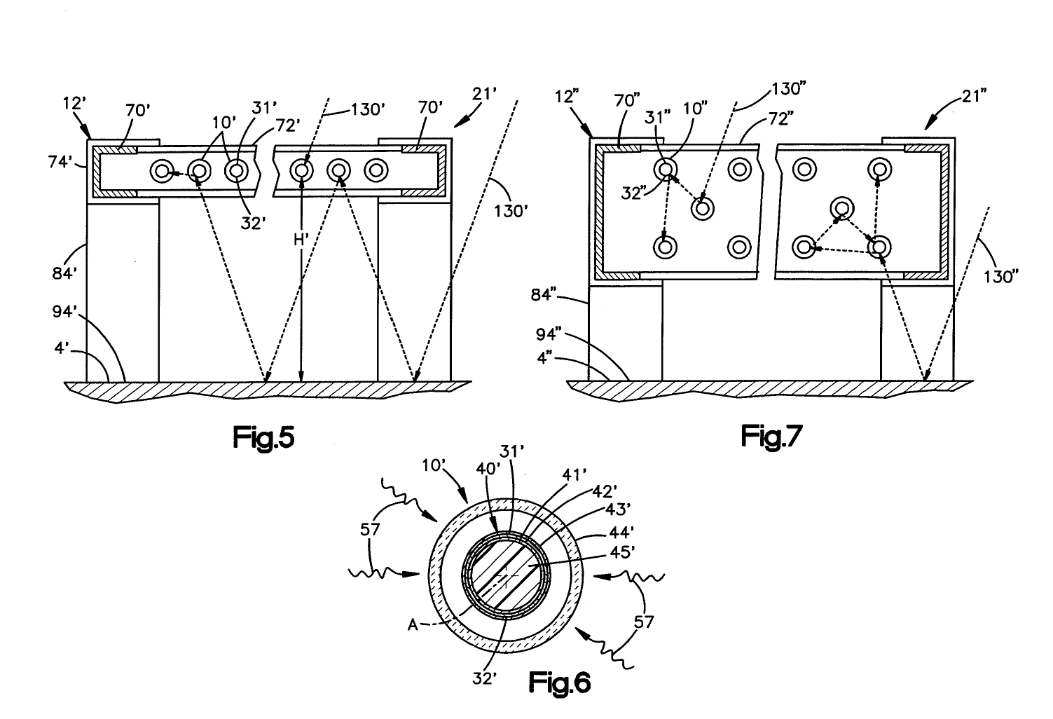

In the solar panel array 1 shown in FIG. 1, each panel 21 has a single flat photovoltaic module 10 adjoining all four rails 70, 72. In an alternative solar panel array 1′ shown in FIGS. 4-5, each panel 21′, 22′, 23′ has multiple rod-shaped cylindrical photovoltaic modules 10′ arranged in a one-dimensional array. Each module 10′ is elongated parallel to the side rails 70′ and is attached only to the end rails 72′. The modules 10′ in each panel 21′ can be aligned perpendicularly to, or in parallel with, the modules 10′ of the panels 22′, 23′ adjacent to it.

As shown in FIG. 6, each module 10′ includes an elongated tubular photocell 40′ overlying a support core 45 and surrounded by a transparent protective tube 44′. Like each photocell 40 of FIG. 3, the photocell 40′ of FIG. 6 includes an inner conductive layer 41′, a middle semiconductor photovoltaic layer 42′, and a transparent conductive outer layer 43′. Accordingly, each module 10′ includes a photovoltaic surface facing in every direction about the module's central axis A, including an upward-facing photovoltaic surface 31′ and a downward-facing photovoltaic surface 32′. Each module 10 can thus photovoltaically generate electricity from light 57 striking the module 10′ from any radially-inward direction.

Referring to FIGS. 4-5, the height H′ of the downward-facing surfaces 32 from the reflective surface 94′ is about 25% to about 100% of the width W₁′ of the panel 21 in the first direction D₁ and of the width W₂′ of the panel 21 in the second direction D₂.

As shown in FIG. 5, light 130′ can strike the photovoltaic surfaces 31′ directly from above. Light passing between adjacent modules 10′ or between adjacent panels 21′, 22′, 23′ (FIG. 4) can be reflected by the reflective surface 94 back toward the photovoltaic surfaces 32′.

In another embodiment, shown in FIG. 7, cylindrical modules 10″ are arranged in a two-dimensional array. A light ray 130″ can be reflected any number of times from any number of photovoltaic surfaces 31″, 32″ and from the reflective surface 94″. The increased number of modules 10″ being struck by the light ray 130″ increases efficiency of converting the light ray 130″ to electricity.

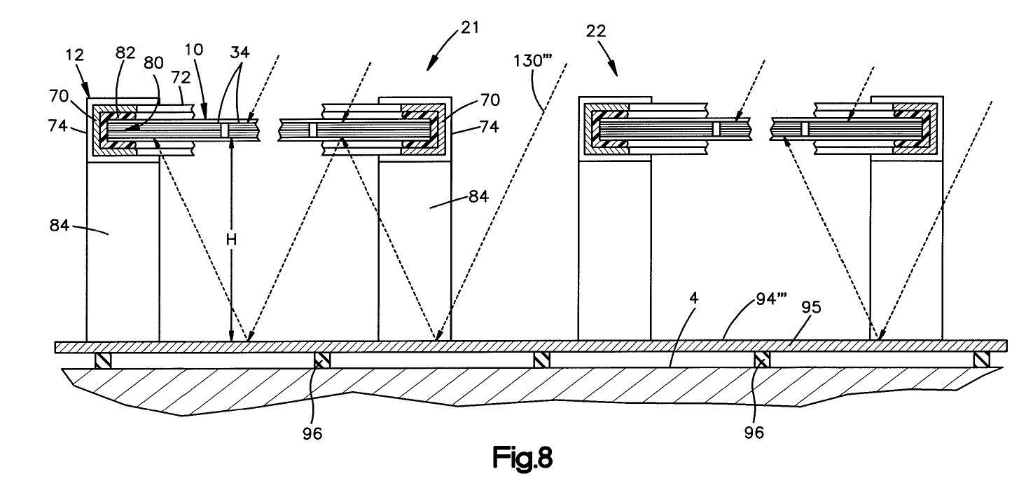

In the first embodiment of FIG. 3, the reflective surface 94 is provided by the support surface 4. In another embodiment, shown in FIG. 8, the reflective surface 94′″ is provided by a reflector 95 that is separate from the support surface 4′″. The reflector 95 in this example is a mirror supported above the ground 4′″ by blocks 96. The panels 21, 22 can rest on the reflector 95 without being attached to it. Or one or more of the panels 21, 22 can be attached to the reflector 95, for the panels 21, 22 and the reflector 95 to be lifted and transported in unison as a single unit.

The apparatus 1 described above thus provides examples of the following features: First and second solar panels are mounted in an operative position. Each panel includes an upward-facing photovoltaic surface and a downward-facing photovoltaic surface that are configured to photovoltaically generate electricity from light. The downward-facing photovoltaic surface is spaced above a reflective surface. The first and second panels are spaced apart in a first direction by a spacing distance S₁ that is about 25% to about 100% of the width W₁ of the first panel in the first direction D₁. Some downwardly-directed light rays can strike the upward-facing photovoltaic surfaces of the panels. Other downwardly-directed light rays can pass between the first and second panels and be reflected upward by the reflective surface to strike the downward-facing photovoltaic surfaces of the panels.

The reflective surface can be a mirror surface. Or it can be a light-diffusing surface, such as provided by a coating of paint or gravel. The reflective surface can be a ground surface or a roof surface, and can be configured to be walked on. The reflective surface can be secured to the first panel or not secured to the first panel. A portion of the reflective surface can be located between the panels, and another portion of the reflective surface can be directly beneath the downward-facing photovoltaic surface. The height H of the downward-facing photovoltaic surface from the reflective surface can be about 25% to about 100% of the width W₁ of the panel in the first direction D₁.

The width W₁ of the first panel in the first direction D₁ and the width W₂ of the first panel in a second direction D₂ perpendicular to the first direction can differ by less than about 5%. The panels can be secured in place or not secured in place. The photovoltaic surfaces of the first panel can be electrically interconnected with those of the second panel.

Each of the panels can include legs that engage the reflective surface to space the downward-facing photovoltaic surface above the reflective surface. The first panel is configured to retain the upward-facing and downward-facing photovoltaic surfaces in a fixed orientation, such as horizontal.

The upward-facing photovoltaic surface and the downward-facing photovoltaic surface of the first panel can each be provided by multiple photocells. The upward-facing photovoltaic surface and the downward-facing photovoltaic surface of the first panel can be provided by one or more bifacial photovoltaic units. As exemplified in FIGS. 5-7, the upward-facing and downward-facing photovoltaic surfaces of the first panel can be radially opposite surface portions of a cylindrical photovoltaic surface, which can be one of multiple cylindrical photovoltaic surfaces of the first panel. The horizontal area defined by and between the first and second panels (bounded by imaginary lines in the example of FIG. 1) is about 25% to about 100% of the horizontal area covered by the first panel.

A third solar panel can also be mounted in an operative position. The third panel can include an upward-facing photovoltaic surface. It can also a downward-facing photovoltaic surface that is spaced above the reflective surface. The first and third panels can be spaced apart in a second direction D₂, perpendicular to the first direction D₁, by a spacing distance S₂ that is about 25% to about 100% of the width W₂ of the first panel in the second direction D₂. Some downwardly-directed light rays can strike the upward-facing photovoltaic surface of the third panel. Other downwardly-directed light rays can pass between the first and third panels and be reflected upward by the reflective surface to strike the downward-facing photovoltaic surfaces of the first and third panels.

The scope of the invention is defined by the claims, and may include other examples that occur to those skilled in the art. Such other examples are intended to be within the scope of the claims if they have elements that do not differ from the literal language of the claims, or if they include equivalent structural elements with insubstantial differences from the literal language of the claims.

1. An apparatus comprising:
first and second solar panels mounted in an operative position, each panel including an upward-facing photovoltaic surface and a downward-facing photovoltaic surface that are configured to photovoltaically generate electricity from light, the downward-facing photovoltaic surface being spaced above a reflective surface;
the first and second panels being spaced apart in a first direction by a spacing distance that is 25%-100% of the width of the first panel in the first direction, for some downwardly-directed light rays to strike the upward-facing photovoltaic surfaces of the panels and for other downwardly-directed light rays to pass between the first and second panels and be reflected upward by the reflective surface to strike the downward-facing photovoltaic surfaces of the panels.

2. The apparatus of claim 1 wherein the reflective surface is a mirror surface.

3. The apparatus of claim 1 wherein the reflective surface is a light-diffusing surface.

5. The apparatus of claim 1 wherein the reflective surface is a ground surface.

6. The apparatus of claim 1 wherein the reflective surface is a roof surface.

7. The apparatus of claim 1 wherein the reflective surface is configured to be walked on.

8. The apparatus of claim 1 wherein the reflective surface is secured to the first panel.

9. The apparatus of claim 1 wherein the reflective surface not secured to the first panel.

10. The apparatus of claim 1 wherein a portion of the reflective surface is located between the panels.

11. The apparatus of claim 1 wherein a portion of the reflective surface is directly beneath the downward-facing photovoltaic surface.

12. The apparatus of claim 1 wherein the height of the downward-facing photovoltaic surface above the reflective surface is about 25% to about 100% of the width of the panel in the first direction.

13. The apparatus of claim 1 wherein the horizontal area defined by and between the first and second panels is about 25% to about 100% of the horizontal area covered by the first panel.

14. The apparatus of claim 1 wherein the width of the first panel in the first direction and the width of the first panel in a second direction perpendicular to the first direction differ by less than about 5%.

15. The apparatus of claim 1 wherein the panels are secured in place.

16. The apparatus of claim 1 wherein are not secured in place.

17. The apparatus of claim 1 wherein the photovoltaic surfaces of the first panel are electrically interconnected with the photovoltaic surfaces of the second panel.

18. The apparatus of claim 1 wherein each of the panels includes legs that engage the reflective surface to space the downward-facing photovoltaic surface above the reflective surface.

19. The apparatus of claim 1 wherein the panel is configured to retain the upward-facing and downward-facing photovoltaic surfaces in a fixed orientation.

20. The apparatus of claim 19 wherein the fixed orientation is horizontal.

21. The apparatus of claim 1 wherein the upward-facing and downward-facing photovoltaic surfaces of the first panel are each provided by multiple photocells.

22. The apparatus of claim 1 wherein the upward-facing and downward-facing photovoltaic surfaces of the first panel are provided by one or more bifacial photovoltaic units.

23. The apparatus of claim 1 wherein the upward-facing and downward-facing photovoltaic surfaces of the first panel are radially opposite surface portions of a cylindrical photovoltaic surface.

24. The apparatus of claim 23 wherein the cylindrical photovoltaic surface is one of multiple cylindrical photovoltaic surfaces of the first panel.

25. The apparatus of claim 1 further comprising a third solar panel mounted in an operative position, the third panel including an upward-facing photovoltaic surface and also a downward-facing photovoltaic surface that is spaced above the reflective surface;
the first and third panels being spaced apart in a second direction, perpendicular to the first direction, by a spacing distance that is about 25% to about 100% of the width of the first panel in the second direction, for some downwardly-directed light rays to strike the upward-facing photovoltaic surface of the third panels and for other downwardly-directed light rays to pass between the first and third panels and be reflected upward by the reflective surface to strike the downward-facing photovoltaic surfaces of the first and third panel.
